(19) United States
(12) Patent Application Publication
(10) Pub. No.: US 2016/0272484 A1
(43) Pub. Date: Sep. 22, 2016

(54) ELECTRONIC DEVICE AND METHOD OF MANUFACTURING THE SAME

(71) Applicant: KABUSHIKI KAISHA TOSHIBA, Tokyo (JP)

(72) Inventors: Tomohiro SAITO, Yokohama Kanagawa (JP); Kei OBARA, Kitakami Iwate (JP)

(73) Assignee: KABUSHIKI KAISHA TOSHIBA, Tokyo (JP)

(21) Appl. No.: 14/843,699

(22) Filed: Sep. 2, 2015

(30) Foreign Application Priority Data
Mar. 16, 2015 (JP) 2015-052307

(51) Int. Cl. B81B 3/00; H01G 5/16; B81C 1/00

(52) U.S. Cl. CPC B81B 3/0078; B81C 1/00682; H01G 5/16

(57) ABSTRACT

According to one embodiment, an electronic device includes a MEMS element provided on an underlying region, and a protection film including a first layer, a second layer provided on the first layer, and a third layer provided on the second layer, the protection film covering the MEMS element and forming a cavity in an inside thereof. An outer periphery of the second layer is located inside an outer periphery of the cavity, as viewed in a direction perpendicular to a surface of the underlying region.

### CROSS-REFERENCE TO RELATED APPLICATIONS

This application is based upon and claims the benefit of priority from Japanese Patent Application No. 2015-052307, filed Mar. 16, 2015, the entire contents of which are incorporated herein by reference.

### FIELD

Embodiments described herein relate generally to an electronic device, and a method of manufacturing the electronic device.

### BACKGROUND

There has been proposed an electronic device in which a MEMS (micro electro mechanical systems) element is provided on a semiconductor substrate. In this electronic device, in usual cases, the MEMS element is covered with a protection film including a plurality of layers.

However, in the above-described electronic device, there is a case in which a crack occurs in the protection film. If a crack occurs, the crack adversely affects the characteristics and reliability of the MEMS element.

Accordingly, there has been a demand for an electronic device and a method of manufacturing the electronic device, which can prevent a crack from occurring in the protection film.

### BRIEF DESCRIPTION OF THE DRAWINGS

FIG. 1 is a cross-sectional view which schematically illustrates the structure of an electronic device according to a first embodiment.

FIG. 2 is a cross-sectional view relating to the first embodiment, which schematically illustrates a part of the structure of a protection film.

FIG. 3 is a view relating to the first embodiment, which schematically illustrates a positional relationship in plan view between a second layer of the protection film and a cavity.

FIG. 4 is a cross-sectional view which schematically illustrates a part of a method of manufacturing the electronic device according to the first embodiment.

FIG. 5 is a cross-sectional view which schematically illustrates a part of the method of manufacturing the electronic device according to the first embodiment.

FIG. 6 is a cross-sectional view which schematically illustrates a part of the method of manufacturing the electronic device according to the first embodiment.

FIG. 7 is a cross-sectional view which schematically illustrates a part of the method of manufacturing the electronic device according to the first embodiment.

FIG. 8 is a graph relating to the first embodiment, which illustrates a simulation result of stress of the protection film.

FIG. 9 is a view relating to the first embodiment, for illustrating a location of the stress simulation of FIG. 8.

FIG. 10 is a cross-sectional view which schematically illustrates a part of a method of manufacturing an electronic device according to a second embodiment.

FIG. 11 is a cross-sectional view which schematically illustrates a part of the method of manufacturing the electronic device according to the second embodiment.

FIG. 12 is a cross-sectional view which schematically illustrates a part of the method of manufacturing the electronic device according to the second embodiment.

FIG. 13 is a cross-sectional view which schematically illustrates a part of the method of manufacturing the electronic device according to the second embodiment.

FIG. 14 is a cross-sectional view which schematically illustrates a part of the method of manufacturing the electronic device according to the second embodiment.

FIG. 15 is a view relating to the second embodiment, which schematically illustrates a shape of an underlying region.

FIG. 16 is a graph relating to the second embodiment, which illustrates a relationship between a warpage amount of a semiconductor wafer and a crack defect rate of the protection film.

### DETAILED DESCRIPTION

In general, according to one embodiment, an electronic device includes: a MEMS element provided on an underlying region; and a protection film including a first layer, a second layer provided on the first layer, and a third layer provided on the second layer, the protection film covering the MEMS element and forming a cavity in an inside thereof. An outer periphery of the second layer is located inside an outer periphery of the cavity, as viewed in a direction perpendicular to a surface of the underlying region.

Various embodiments will be described hereinafter with reference to the accompanying drawings.

### Embodiment 1

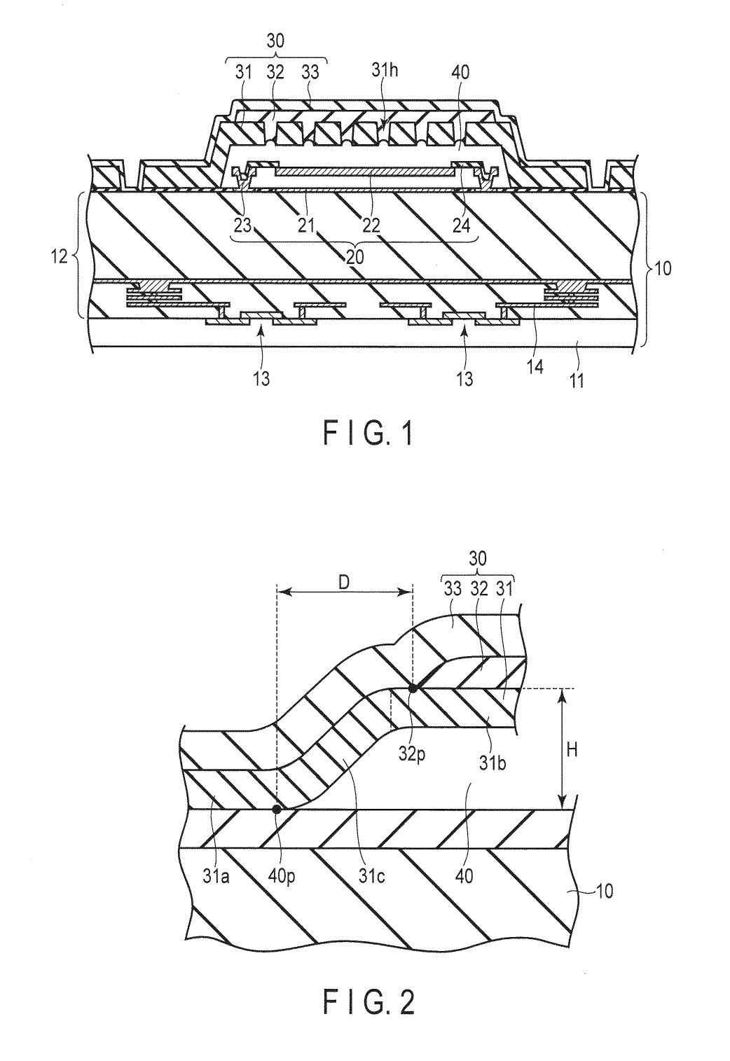

FIG. 1 is a cross-sectional view which schematically illustrates the structure of an electronic device according to a first embodiment. A MEMS element 20 is provided on an underlying region 10. The MEMS element 20 is covered with a dome-shaped protection film 30.

The underlying region 10 includes a semiconductor substrate 11, an insulation region 12 provided on the semiconductor substrate 11, a transistor 13 provided on a surface region of the semiconductor substrate 11, and a wiring 14 provided in the insulation region 12.

The MEMS element 20 is used as a variable capacitor. Specifically, the MEMS element (variable capacitor) 20 includes a lower electrode 21, an upper electrode 22, an anchor portion 23, and a spring portion 24 which connects the upper electrode 22 and anchor portion 23. If a voltage is applied between the lower electrode 21 and upper electrode 22, the distance between the lower electrode 21 and upper electrode 22 varies due to electrostatic force, and the capacitance of the MEMS element (variable capacitor) 20 varies.

The protection film 30 includes a first layer 31, a second layer 32 provided on the first layer 31, and a third layer 33 provided on the second layer 32. The protection film 30 covers the MEMS element 20, and a cavity 40 is formed in an inside of the protection film 30.

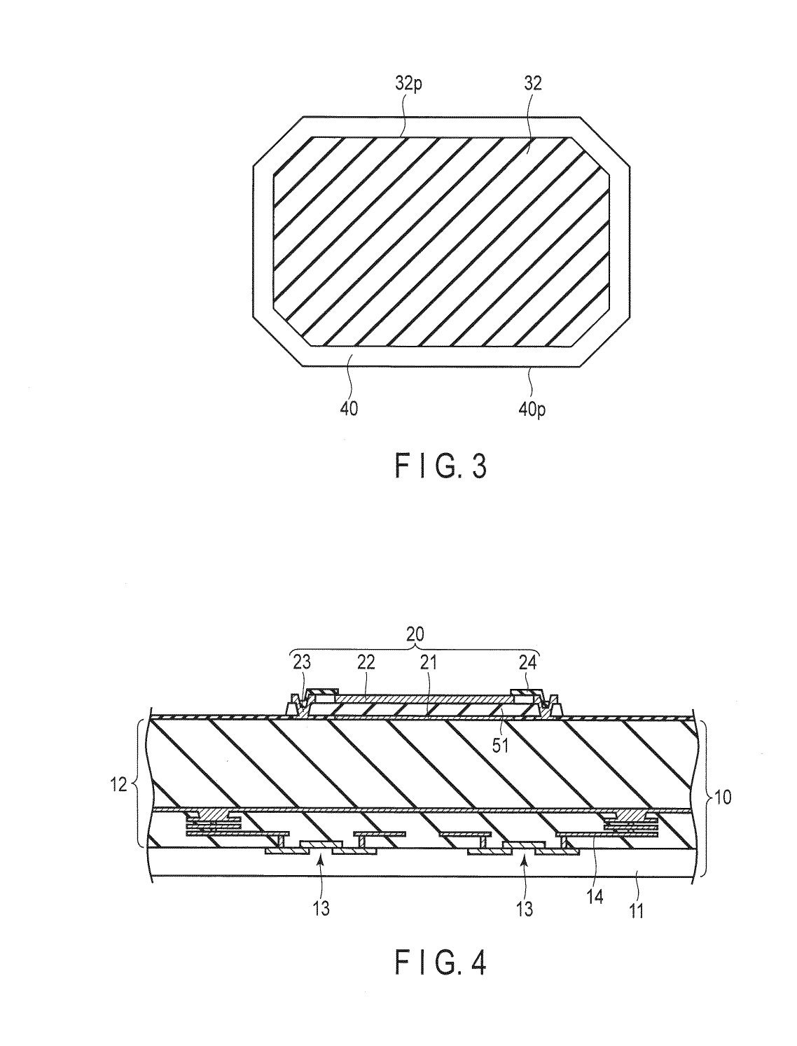

FIG. 2 is a cross-sectional view which schematically illustrates a part of the structure of the protection film 30 shown in FIG. 1. FIG. 3 is a view which schematically illustrates a positional relationship in plan view between the second layer 32 of the protection film 30 and the cavity 40.

As illustrated in FIG. 1, FIG. 2 and FIG. 3, an outer periphery 32p of the second layer 32 of the protection film 30 is located inside an outer periphery 40p of the cavity 40, as viewed in a direction perpendicular to the surface of the underlying region 10. As illustrated in FIG. 2, the outer periphery 32p of the second layer 32 corresponds to a terminal end position of the second layer 32. The outer periphery 40p of the cavity 40 corresponds to a terminal end position of the cavity 40.

In addition, the first layer 31 of the protection film 30 includes a first portion 31a which is fixed on the underlying region 10, a second portion 31b which is located above the underlying region 10 and is substantially parallel to the surface of the underlying region 10, and a third portion 31c which is located between the first portion 31a and second portion 31b and is inclined. The above-described outer periphery 32p of the second layer 32 is located on the second portion 31b. A plurality of holes 31h are provided in the second portion 31b of the first layer 31, and the second layer 32 fills in these holes 31h. In addition, the third layer 33 covers the outer periphery 32p of the second layer 32.

As illustrated in FIG. 2, if the height of the second portion 31b of the first layer 31 is H and the angle of inclination of the third portion 31c is p, a distance D in the horizontal direction between the outer periphery 32p of the second layer 32 and the outer periphery 40p of the cavity 40 is greater than H/tanφ. For example, if the height H of the second portion 31b is 10 μm and the angle of inclination of the third portion 31c is 45 degrees, the distance D is greater than 10 μm. In addition, it is preferable that the outer periphery 32p of the second layer 32 is apart from the boundary between the second portion 31b and third portion 31c by 1 μm or more, so that the outer periphery 32p of the second layer 32 may surely be located on the the second portion 31b. It is also preferable that the distance D is greater than 15 μm, since both ends of the third portion 31c are rounded.

The first layer 31 is formed of a material containing silicon and oxygen. Concretely, the first layer 31 is formed of silicon oxide. The plural holes 31h provided in the first layer 31 are provided in order to form the cavity 40 by removing a sacrificial film (to be described later).

The second layer 32 is formed of an organic substance. Concretely, the second layer 32 is formed of polyimide. The second layer 32 is used in order to fill in the plural holes 31h provided in the first layer 31 after the cavity 40 is formed.

The third layer 33 is formed of a material containing silicon and nitrogen. Concretely, the third layer 33 is formed of silicon nitride. The third layer 33 has a high moisture-proof property, and can prevent entrance of moisture into the cavity 40. Specifically, the third layer 33 has a less moisture permeability than the second layer 32.

Next, a method of manufacturing the electronic device according to the embodiment is described with reference to FIG. 4 to FIG. 7, and FIG. 1.

To start with, as illustrated in FIG. 4, a MEMS element 20 is formed on the underlying region 10. Concretely, a metallic film (e.g. aluminum alloy film) is formed on the insulation region 12. Subsequently, the metallic film is patterned by anisotropic etching, thereby forming a pattern of the lower electrode 21 and a lower pattern of the anchor portion 23.

Next, a silicon nitride film is formed on the lower electrode 21 as an insulation film (not shown) for a capacitor. Subsequently, a sacrificial film 51 is formed over the entire surface in order to provide a space between the lower electrode and upper electrode, and then the sacrificial film 51 is patterned.

Next, a metallic film for the upper electrode is formed over the entire surface, and this metallic film is patterned. Subsequently, in order to form a spring portion for connecting the upper electrode and anchor portion, a brittle material, such as a silicon nitride film, is formed on the entire surface, and this brittle material is patterned. In this manner, the pattern of the upper electrode 22, the upper pattern of the anchor portion 23 and the pattern of the spring portion 24 are formed.

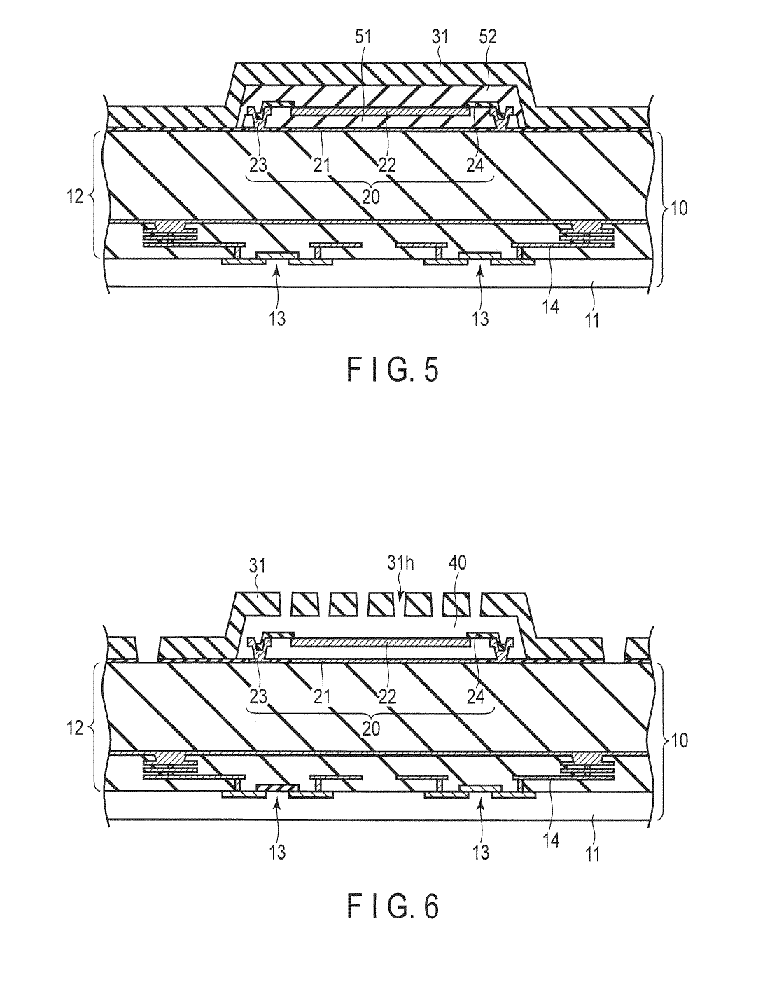

Next, as illustrated in FIG. 5, in order to form a cavity, a sacrificial film 52 is formed on the entire surface, and this sacrificial film 52 is patterned. Subsequently, a first layer 31 of the protection film 30 is formed on the entire surface. A silicon oxide film is used for the first layer 31.

Next, as illustrated in FIG. 6, the first layer 31 is patterned, and a plurality of holes 31h are formed in the first layer 31. As illustrated in FIG. 1 and

FIG. 2, all holes 31h are formed in the second portion 31b of the first layer 31. Subsequently, the sacrificial films 51 and 52 are removed by ashing. Specifically, the sacrificial films 51 and 52 are removed by supplying an ashing gas through the plural holes 31h. As a result, the cavity 40 is formed inside the first layer 31.

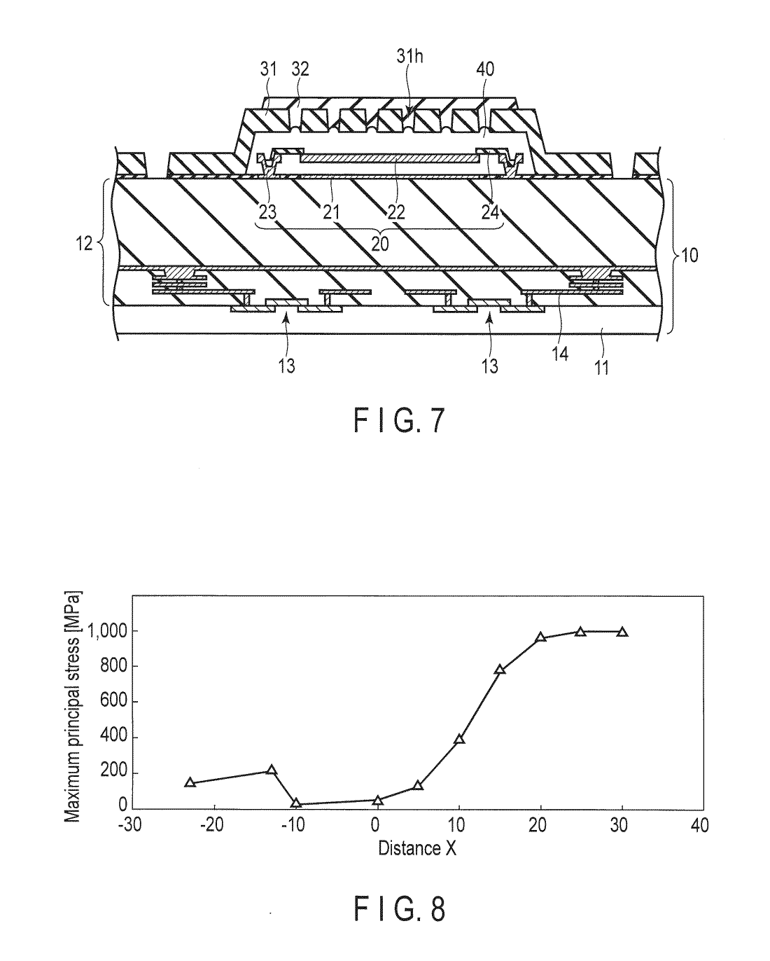

Next, as illustrated in FIG. 7, a second layer 32 of the protection film 30 is formed on the entire surface, and the second layer 32 is patterned. A polyimide is used for the second layer 32. The holes 31h formed in the first layer 31 are all filled with the second layer 32. In this fabrication step, the second layer 32 is patterned such that the outer periphery of the pattern of the second layer 32 is located inside the outer periphery of the cavity 40. The second layer 32 is formed on the first layer 31, and is also formed in the holes 31h.

At last, as illustrated in FIG. 1, a third layer 33 of the protection film 30 is formed on the entire surface, and the third layer 33 is patterned. A silicon nitride film is used for the third layer 33. The third layer 33 has a high moisture-proof property, and can prevent entrance of moisture into the cavity 40.

In this manner, the protection film (thin-film dome) 30, which includes the first layer 31, second layer 32 and third layer 33, is formed.

As has been described above, in the present embodiment, the outer periphery 32p of the second layer 32 of the protection film 30 is located inside the outer periphery 40p of the cavity 40, as viewed in the direction perpendicular to the surface of the underlying region 10. By this structure, the stress of the protection film 30 can be decreased, and the occurrence of a crack in the protection film 30 can be prevented. As a result, degradation in characteristics and reliability of the MEMS element 20 can be prevented.

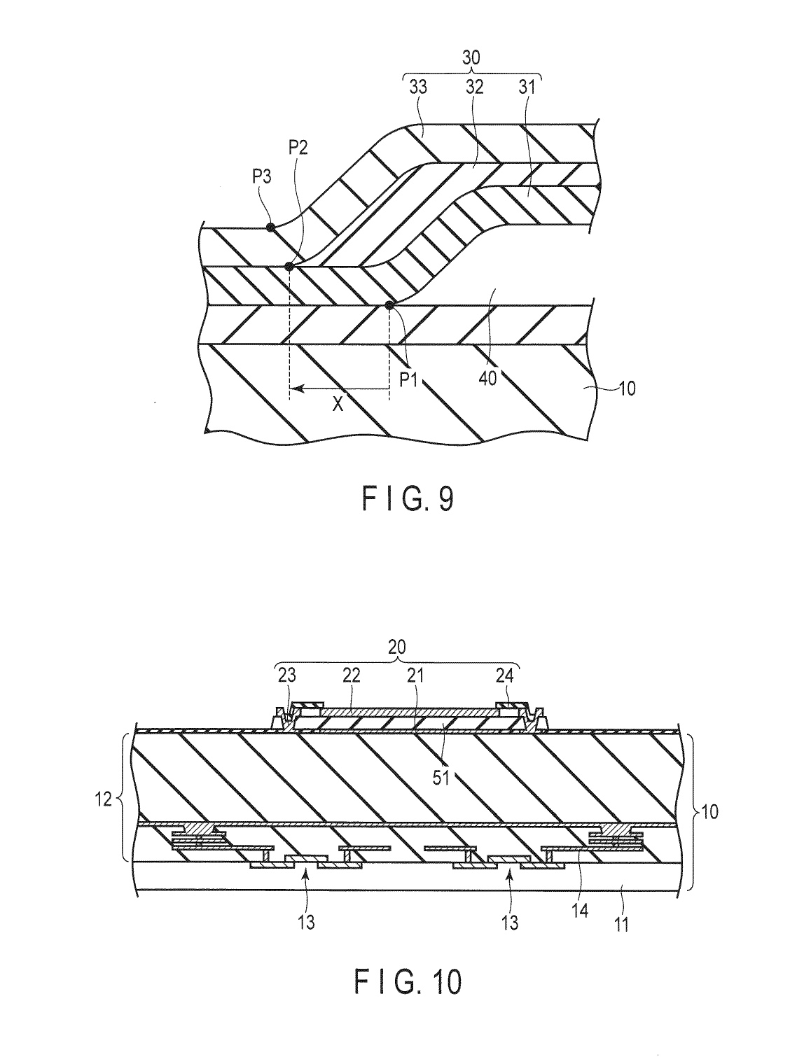

FIG. 8 is a graph which illustrates a simulation result of the stress of the protection film 30. FIG. 9 is a view for illustrating a location of the stress simulation of FIG. 8.

In FIG. 9, a point P1 is a point on the outer periphery of the cavity 40, and corresponds to the origin of the abscissa in FIG. 8. A point P2 is a point on the outer periphery of the second layer 32 of the protection film 30. A distance X in the horizontal direction of the point P2, with the point P1 being set as the origin, corresponds to the abscissa in FIG. 8. The direction of an arrow of X in FIG. 9 corresponds to a positive direction of the abscissa in FIG. 8. A point P3 indicates a stress simulation location.

Incidentally, FIG. 8 illustrates a simulation result of stress under normal pressure at 20° C. after the formation of the third layer (silicon nitride film) 33.

As illustrated in FIG. 8, if the X value increases from zero in the positive direction, the stress also increases. However, when the X value is negative, no large stress occurs. It is thus understood that the stress of the protection film 30 is decreased when the X value is negative, that is, the outer periphery of the second layer 32 of the protection film 30 is located inside the outer periphery of the cavity 40.

Therefore, by using the structure of the present embodiment, the stress of the protection film 30 can be reduced, and the occurrence of a crack in the protection film 30 can be prevented.

Furthermore, in the present embodiment, since the outer periphery 32p of the second layer 32 of the protection film 30 is located inside the outer periphery 40p of the cavity 40, the area of the protection film 30 can be decreased. Therefore, a compact electronic device can be obtained.

### Embodiment 2

Next, a second embodiment is described. Incidentally, since the basic matters are the same as in the above-described first embodiment, a description of the matters described in the first embodiment is omitted.

FIG. 10 to FIG. 14 are cross-sectional views which schematically illustrate a method of manufacturing an electronic device according to the present embodiment.

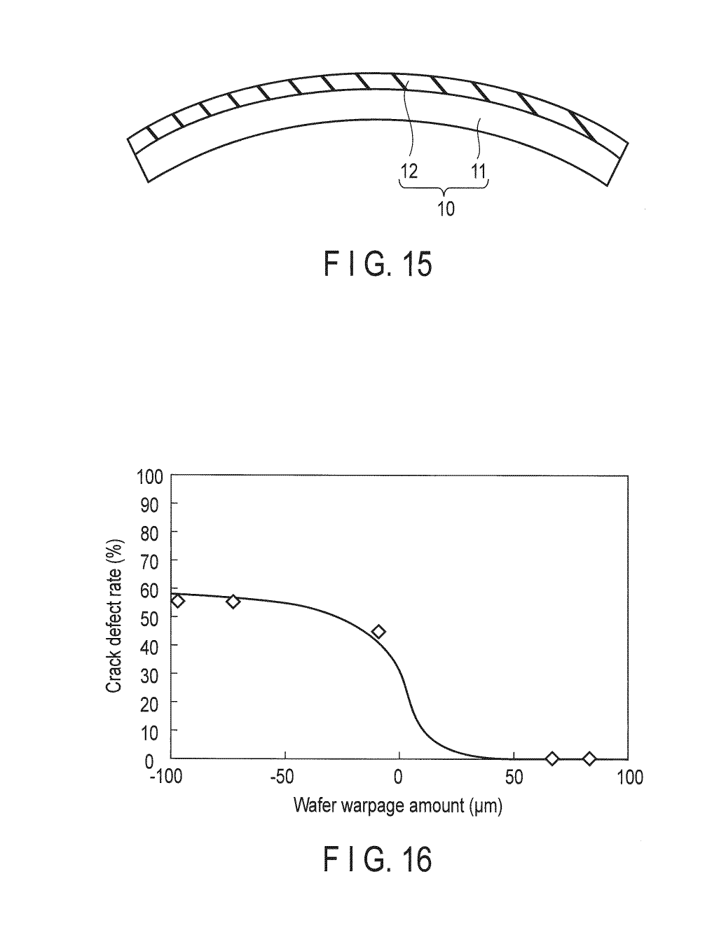

To start with, in a fabrication step of FIG. 10, an underlying region 10 having a convex upper surface, as illustrated in FIG. 15, is formed. The underlying region 10 includes a semiconductor substrate (semiconductor wafer) 11 and an insulation region 12 provided on the semiconductor substrate 11, and an insulation film included in the insulation region 12 has compressive stress. This insulation film is formed of a material containing silicon and oxygen. Concretely, this insulation film is formed of silicon oxide. By controlling film-formation conditions, an insulation film with compressive stress can be formed. Because of the insulation film having the compressive stress, the entirety of the insulation region 12, too, has compressive stress. As a result, the underlying region 10 having the convex upper surface can be formed.

Next, like the step of FIG. 4 of the first embodiment, a MEMS element 20 and a sacrificial film 51 are formed on the underlying region 10 with the convex upper surface.

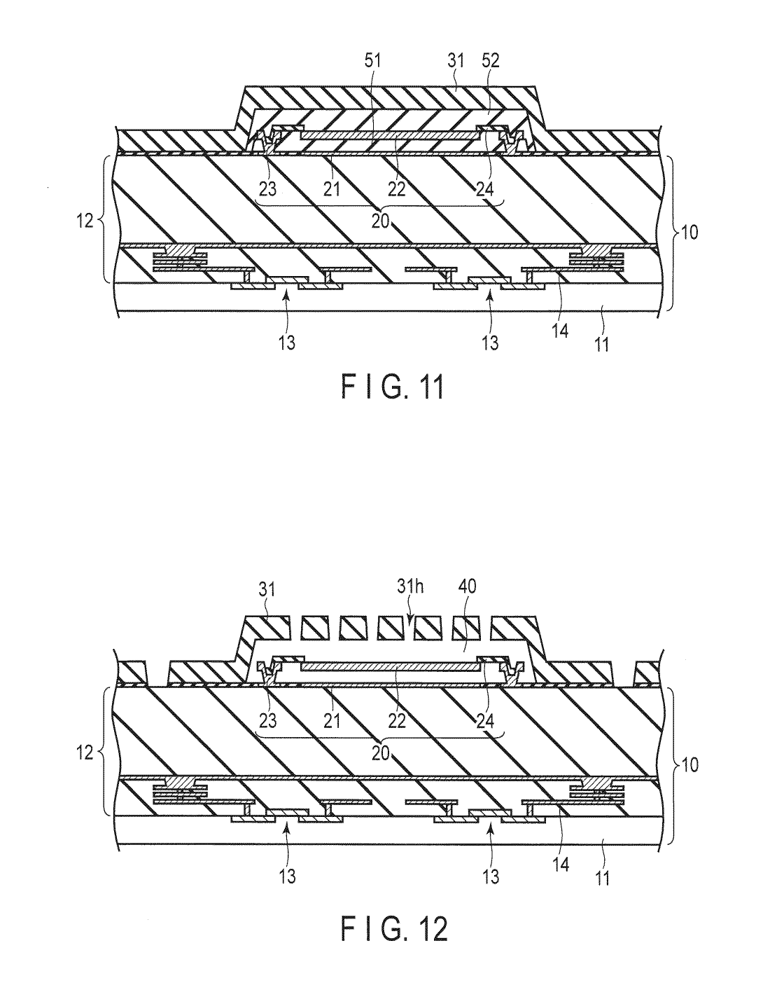

Subsequently, as illustrated in FIG. 11, like the step of FIG. 5 of the first embodiment, a sacrificial film 52 and a first layer 31 of the protection film 30 are formed.

Next, as illustrated in FIG. 12, like the step of FIG. 6 of the first embodiment, a plurality of holes 31h are formed in the first layer 31, and a cavity 40 is formed inside the first layer 31.

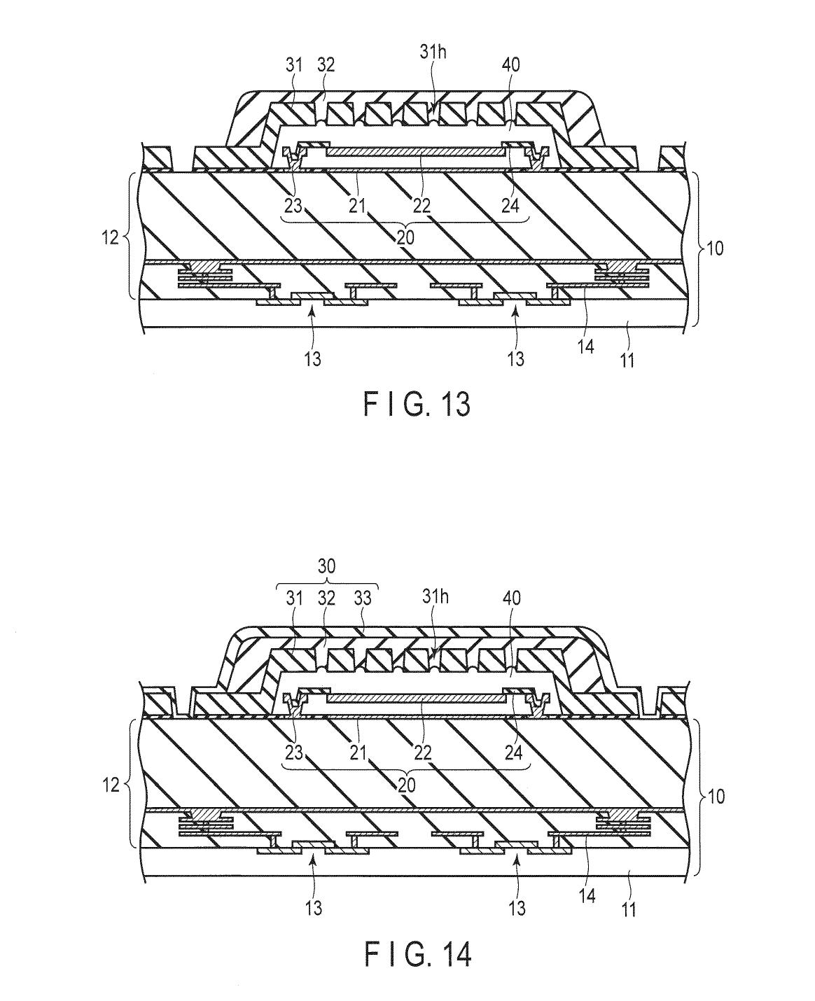

Subsequently, as illustrated in FIG. 13, like the step of FIG. 7 of the first embodiment, a second layer 32 of the protection film 30 is formed. In the present embodiment, however, the outer periphery of the pattern of the second layer 32 is located outside the outer periphery of the cavity 40. Like the first embodiment, the outer periphery of the pattern of the second layer 32 may be located inside the outer periphery of the cavity 40.

At last, as illustrated in FIG. 14, a third layer 33 of the protection film 30 is formed.

In this manner, the protection film (thin-film dome) 30 is formed which includes the first layer 31, the second layer 32 provided on the first layer 31, and the third layer 33 provided on the second layer 32, and which covers the MEMS element 20 and forms the cavity 40 in the inside thereof.

FIG. 16 is a graph which illustrates a relationship between a warpage amount of the semiconductor wafer and a crack defect rate of the protection film 30, after the silicon oxide film was formed as the insulation film of the insulation region 12 on the semiconductor substrate (semiconductor wafer) 11. The thickness of the insulation film is 5 μm.

As illustrated in FIG. 16, in the case in which the warpage amount is negative (the case in which the semiconductor wafer and insulation film have concave upper surfaces), the crack defect rate is large. On the other hand, in the case in which the warpage amount is positive (the case in which the semiconductor wafer and insulation film have convex upper surfaces, as in the case of the present embodiment), the crack defect rate is very small. Accordingly, as in the present embodiment, by forming the underlying region 10 having the convex upper surface, the stress of the protection film 30 is decreased, and the crack defect rate of the protection film 30 can greatly be reduced.

As has been described above, in the present embodiment, the MEMS element 20 and protection film 30 are formed on the underlying region 10 with the convex upper surface. By this method, the stress of the protection film 30 can be decreased, and the occurrence of a crack in the protection film 30 can be prevented. As a result, the characteristics and reliability of the MEMS element 20 can be enhanced.

Incidentally, in the above-described first and second embodiments, the variable capacitor (MEMS element) adopts a method of driving the electrodes by electrostatic force, but the variable capacitor (MEMS element) may adopt a method of driving the electrodes by piezoelectric force.

In addition, it is possible to partially modify the structure of the above-described variable capacitor, and to use the modified structure as a switch. Specifically, a part of the insulation film for the capacitor is removed, and the lower electrode is exposed. By this structure, the upper electrode and lower electrode can be put in direct contact, and a switch can be constituted.

Additionally, in the above-described first and second embodiments, the lower electrode is fixed and only the upper electrode is movable. Alternatively, both the lower electrode and the upper electrode may be movable.

Additionally, in the first and second embodiments, the MEMS element is constituted by using two electrodes, namely the lower electrode and upper electrode. Alternatively, the MEMS element may be constituted by using three or more electrodes. For example, the lower electrode and upper electrode may be fixed, and an intermediate electrode, which is movable, may be provided between the lower electrode and upper electrode.

Additionally, although the connection between the transistor 13 and MEMS element 20 is not illustrated in FIG. 1, etc., the transistor 13 and MEMS element 20 may be connected by a contact.

Additionally, although a shield layer in the insulation region 12 is provided over the entire surface in FIG. 1, etc., the shield layer may be divided, for example, at a central part in FIG. 1, etc. Additionally, a signal output line of the MEMS element 20 is not illustrated in FIG. 1, etc. However, in fact, the signal output line and terminal are also provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a MEMS element provided on an underlying region; and
a protection film including a first layer, a second layer provided on the first layer, and a third layer provided on the second layer, the protection film covering the MEMS element and forming a cavity in an inside thereof,
wherein an outer periphery of the second layer is located inside an outer periphery of the cavity, as viewed in a direction perpendicular to a surface of the underlying region.

2. The electronic device of claim 1, wherein the first layer includes a first portion which is fixed on the underlying region, a second portion which is located above the underlying region and is substantially parallel to the surface of the underlying region, and a third portion which is located between the first portion and the second portion and is inclined, and
the outer periphery of the second layer is located on the second portion.

3. The electronic device of claim 2, wherein the second layer fills in a plurality of holes provided in the second portion of the first layer.

4. The electronic device of claim 1, wherein the third layer covers the outer periphery of the second layer.

5. The electronic device of claim 1, wherein the first layer contains silicon and oxygen.

6. The electronic device of claim 1, wherein the second layer is formed of an organic substance.

7. The electronic device of claim 1, wherein the second layer is formed of polyimide.

8. The electronic device of claim 1, wherein the third layer contains silicon and nitrogen.

9. The electronic device of claim 1, wherein the underlying region includes a semiconductor substrate, and an insulation region provided on the semiconductor substrate.

10. The electronic device of claim 1, wherein the MEMS element is used as a variable capacitor.

11. A method of manufacturing an electronic device, comprising:
forming a MEMS element on an underlying region with a convex upper surface; and
forming a protection film including a first layer, a second layer provided on the first layer, and a third layer provided on the second layer, the protection film covering the MEMS element and forming a cavity in an inside thereof.

12. The method of claim 11, wherein the underlying region includes a semiconductor substrate, and an insulation region provided on the semiconductor substrate.

13. The method of claim 12, wherein the insulation region includes an insulation film having compressive stress.

14. The method of claim 13, wherein the insulation film included in the insulation region includes a silicon oxide film.

15. The method of claim 11, wherein the first layer contains silicon and oxygen.

16. The method of claim 11, wherein the second layer is formed of an organic substance.

17. The method of claim 11, wherein the second layer is formed of polyimide.

18. The method of claim 11, wherein the third layer contains silicon and nitrogen.

19. The method of claim 11, wherein the MEMS element is used as a variable capacitor.
